(19) United States
(12) Patent Application Publication
(10) Pub. No.: US 2008/0277756 A1
(43) Pub. Date: Nov. 13, 2008

(54) ELECTRONIC DEVICE AND METHOD FOR OPERATING A MEMORY CIRCUIT

(75) Inventors: Won Gi Min, Chandler, AZ (US); Jiang-Kai Zuo, Chandler, AZ (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: FREESCALE SEMICONDUCTOR, INC., Austin, TX (US)

(21) Appl. No.: 11/746,118

(22) Filed: May 9, 2007

(51) Int. Cl. H01L 29/00; H01L 21/82

(52) U.S. Cl. 257/529; 438/132; 257/E23.149; 257/E23.147

(57) ABSTRACT

An electronic device is disclosed having a dielectric layer (12) formed at a semiconductor substrate (10). A polysilicon fuse structure (14) having a first length is formed overlying the dielectric layer (12). First and second portions (141, 142) of the polysilicon fuse structure are silicided, wherein a third portion (143) of the polysilicon fuse structure (114) that abuts the first portion (141) and the second portion (142) of the polysilicon fuse remains unsilicided.

### FIELD OF THE DISCLOSURE

The present disclosure relates generally to electronic devices, and more particularly to electronic devices with a fuse element.

### BACKGROUND

One-time programmable non-volatile memories (OTPs) have been widely used in analog and digital circuits. An OTP memory can be realized using fuse elements having programmable links. Prior to programming, fuse elements are at an unprogrammed state that can be read by read circuitry as representing a first logic state. After programming, fuse elements are at a programmed state that can be read by the read circuitry as representing a second logic state that is opposite the first logic state. The programming of fuse elements is also referred to as blowing a fuse, since a fuse link region of the fuse element is altered, i.e., destroyed, during programming in a manner that prevents the fuse element from returning to its unprogrammed state. For example, a fuse element manufactured to have a low impedance path, e.g., a short circuit, in an unprogrammed state can be programmed (blown) by causing a conductive portion of the fuse element responsible for the low impedance path to be destroyed, thereby creating a high-impedance path, e.g., an open circuit, across the fuse element. The relatively large amount of current typically needed to program a fuse element creates a need for additional power to program the fuse elements and additional area to support the circuits needed to program the fuse elements. Therefore, a device or method of overcoming these issues would be useful.

### BRIEF DESCRIPTION OF THE DRAWINGS

The present disclosure may be better understood, and its numerous features and advantages made apparent to those skilled in the art by referencing the accompanying drawings, in which like reference numbers indicate similar or identical items.

FIGS. 1-7 illustrate top and cross-sectional views of a fuse element in accordance with an embodiment of the present disclosure;

FIGS. 8 and 9 illustrate cross-sectional views of a fuse element in accordance with a another embodiment of the present disclosure;

FIGS. 10 and 11 illustrate top and cross-sectional views of a fuse element in accordance with an embodiment of the present disclosure;

FIG. 12 illustrates a top view of a fuse element in accordance with a specific embodiment of the present disclosure;

FIG. 13 illustrates a cross-sectional view of a fuse element in accordance with a specific embodiment of the present disclosure; and

FIG. 14 illustrates a flow diagram of a specific embodiment of the present disclosure.

### DETAILED DESCRIPTION

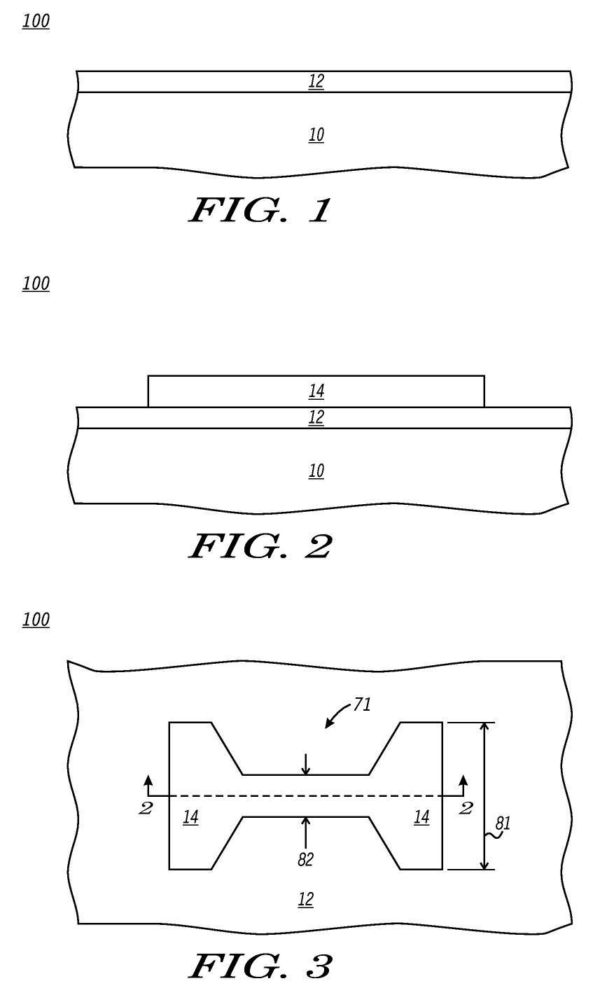

An electronic device is disclosed having a programmable fuse element. In one embodiment, the programmable fuse element includes a semiconductor structure of a first length formed overlying a dielectric layer. The semiconductor structure can be a polysilicon structure, and is discontinuously silicided, whereby first and second portions of the semiconductor structure are silicided, while a third portion of the polysilicon structure that is between and abutting the first portion and the second portion remains unsilicided. During programming current passes through the discontinuously silicided semiconductor structure causing an elevated temperature at the non-silicided portion. The elevated temperature at the non-silicided portion of the semiconductor structure assists in programming of the fuse element. Specific embodiments of the present disclosure will be better understood with reference to FIGS. 1-14.

FIGS. 1-7 are top and cross-sectional views of a location of a workpiece 100 at which a specific embodiment of a fuse element is being formed. It will be appreciated that the term “anti-fuse” is generally used to refer to a one-time programmable element having a fuse link that is more conductive after programming than before programming, and the term “fuse” is generally used to refer to a one-time programmable element having a fuse link that is more conductive prior to programming than after programming. However, with respect to the present application, the term “pro-fuse” is used to refer to a one-time programmable element that is more conductive prior to programming than after programming, and the term “fuse” is used generically to refer to either a pro-fuse or an anti-fuse.

At FIG. 1, a dielectric layer 12 has been formed at a substrate 10 of workpiece 100. The substrate 10 can include a bulk semiconductor substrate or a semiconductor on insulator (SOI) substrate comprising a support layer, an insulating layer, and a semiconductor layer. The bulk substrate and the semiconductor layer of an SOI substrate can include a semiconductor, such as silicon, germanium, carbon, SiGe, SiC, Si—Ge—C, or any combination thereof. The dielectric layer 12 can be an STI (shallow trench isolation) region, a gate dielectric layer, an inter-level dielectric layer, and the like. The dielectric layer 12 can be a low-k or high-k dielectric that can be grown, deposited, or otherwise formed, such as deposited silicon dioxide, a nitride, an oxynitride, hafnium oxide, hafnium silicate, and like compounds with electrical insulating properties, or any combination thereof.

At FIG. 2, a polysilicon structure 14 of a fuse element has been formed overlying the dielectric layer 12 at workpiece 100. In one embodiment, the polysilicon structure 14 is a layer of polysilicon, which can be one of a plurality of separate structures formed by patterning a common polysilicon layer. For example, structure 14 can be patterned from a mask that also forms gate electrodes, resistors, fuse elements, and other front-end-of-line (FEOL) structures. Alternatively, the polysilicon structure 14 can be formed at an interconnect layer, i.e., dielectric 12 is an inter-level dielectric, that overlies front-end-of-line structures, such as gate electrodes of transistors. Furthermore, polysilicon structure 14 can be one of an N-type region, a P-type region, or an undoped region. Doping of polysilicon structure 14 can occur before or after patterning. Note that the term “polysilicon structure” is used with reference numeral herein 14 to refer to a structure that includes a specific semiconductor material. However, it will be appreciated that other semiconductor structures containing polysilicon can be used. For example, semiconductor structures including semiconductor materials previously listed can be used in either a polycrystalline or amorphous state.

In one embodiment, polysilicon structure 14 is formed by a doping process that implants an N-type dopant that can also simultaneously form lightly-doped drain regions of a transistor having a gate electrode formed from the same polysilicon layer used to form polysilicon structure 14. In another embodiment, the polysilicon structure 14 is formed from a P-type layer that is also used to facilitate formation of resister structures.

Note that the terms P-type and N-type as used herein are intended to indicate a predominant dopant-type at a region. For example, a region is referred to as a P-type region or a P conductivity-type when a concentration of P-dopants at the region is greater than a concentration of N-dopants at the region. Similarly, a region is referred to as an N-type region or an N conductivity-type when a concentration of N-dopants at the region is greater than a concentration of P-dopants at the region. Therefore, it will be appreciated by one skilled in the art that a region of one dopant conductivity-type, such as a P-type region, can become a region of the other dopant conductivity-type, an N-type region, by implanting N-type dopants at the region to cause a greater concentration of N-dopants at the region than the pre-existing P-type dopants.

FIG. 3 is a plan view of workpiece 100 that indicates a location of the cross-sectional view of FIG. 2. In addition, FIG. 3 illustrates an embodiment whereby the portion of polysilicon structure 14 has a maximum width 81 at either end of the polysilicon structure 14, and a minimum width 82 between the maximum width portions. The minimum width 82 is chosen to assure easy trimming at low program current, while the maximum width is typically chosen to facilitate enough space for contact plugs to allow a current to flow that will trim a portion of polysilicon structure 14 having the minimum width 82. It will be readily appreciated that structures with additional variances in width can be used, as well as structures with no variance in width.

FIG. 4 illustrates the workpiece 100 after formation of a blocking structure 16. In accordance with a specific embodiment, the blocking structure 16 is a dielectric formed by patterning a larger dielectric layer formed overlying polysilicon structure 14, that further results in formation of sidewall structures 17 as a result of an anisotropic etch. It will be appreciated that the sidewall structures 17 will generally be present when polysilicon structure 14 is formed from the same layer as a gate electrode, and will not necessarily be present for other embodiments. The blocking structure 16 can be any material that acts as a silicide block, which prevents formation of a silicide at a portion of semiconductor structure 14, as described herein. A dielectric blocking structure can be a low-k or high-k dielectric, such as an oxygen containing material, a nitrogen containing material, other materials with electrical insulating properties, and combinations thereof. For example, a nitride having a thickness of approximately 900 angstroms can be used as the blocking structure 16 while the layer 14 has a thickness of approximately 1500 angstroms. The portion of blocking structure 16 overlying the polysilicon structure 14 at the fuse element location illustrated at FIG. 4 is a silicide block that will subsequently prevent a portion of the polysilicon structure 14 immediately under blocking structure 16 from being silicided during a subsequent silicidation process.

At FIG. 5 the workpiece 100 has been exposed to a silicidation process that has formed a silicide 1014 at a silicided portion 141 and a silicided portion 143, which are regions of polysilicon structure 14 that are not covered by blocking structure 16. Since blocking structure 16 is a silicide block, i.e., a structure that blocks the formation of silicide at an underlying structure, an unsilicided portion 142 of polysilicon structure 14 remains underlying and abutting the blocking structure 16. The resulting structure is such that the unsilicided portion 142 of the polysilicon structure 14 is between and abutting the silicided portions 141 and 143 of polysilicon structure 14. The resulting polysilicon structure 14 has a combined length that is equal to the sum of the length of the silicided portions 141 and 143 and the unsilicided portion 142.

FIG. 6 illustrates the workpiece 100 subsequent to formation of an interconnect level that includes conductive inter-level interconnects 20, dielectric layer 22, metal lines 32, and 33, and dielectric layer 34. The conductive inter-level interconnects 20 are generally referred to as either contact plugs or vias. The term contact plugs is generally used when polysilicon structure 14 is formed by patterning a polysilicon layer from a front-end-of-line process that is also used to form gate electrodes for transistors. However, it will be appreciated that in an alternate embodiment, the conductive inter-level interconnects 20 can represent vias, whereby polysilicon structure 14 is formed from a polysilicon layer that is formed subsequent to formation of gate electrodes. In accordance with a specific embodiment, the number of vias or contacts at each end of polysilicon structure 14 is selected to assure a current applied to polysilicon structure 14 during programming will not affect the integrity of vias or contacts in an unexpected manner.

FIG. 7 is a top view of workpiece 100 that indicates the relative location of polysilicon structure 14 to the blocking structure 16. As illustrated, blocking structure 16 of the illustrated fuse element is centered between the contact locations 20, such that a location of the polysilicon structure 14 that is equal-distant from a location of the center contact 20 on the left and a location of the center contact 20 on the right is an unsilicided portion of the polysilicon structure 14. In one embodiment the length between the center vias, or contact plug, can be about 10 times the minimum width of the fuse link. In one embodiment, this length is less than 2 micrometers.

In operation, the pro-fuse element illustrated at FIG. 6 is programmed by applying a programming current through the polysilicon structure 14, which contains the fuse link of the pro-fuse element. The resistance of the polysilicon structure 14 is determined by the un-silicided portion of the discontinuous silicide of the pro-fuse element of FIG. 6. This resistance can be in the kilo-ohm range for a 0.13-micron process and at least partially defines the fuse link location of the fuse element of FIG. 6. Specifically, since the unsilicided portion 142 has a higher resistance, Joule heat is localized when program current passes between the unsilicided region through the selectively silicided region of polysilicon structure 14 of the fuse element, causing the unsilicided portion of the polysilicon structure to heat-up faster than the silicided portions of the polysilicon structure 14 resulting a faster breakdown of the fuse element at the un-silicided portion that is more localized than if the entire polysilicon structure 14 were silicided. Therefore, a location of where the fuse link of the fuse element fails can be controlled with more precision than with previous fuse elements. It has been demonstrated that a pro-fuse element as illustrated in FIG. 6 can be programmed using approximately one-fourth the current of a conventional fuse element, by concentrating the thermal energy to a specific location of the fuse element. For example, a program current of 11 mA or less through the pro-fuse element of FIG. 6 using 0.13-micron CMOS process can program the fuse element. Therefore, the fuse element of FIG. 6 has a conductive conductivity state, e.g., a short circuit, prior to programming that is more conductive to current than its non-conductive conductivity state, e.g., an open circuit, after programming. It will be appreciated that a fuse element at a conductive conductivity state allows more current to flow at an operating voltage used to read the fuse element than the same fuse element will allow to flow when at its non-conductive conductivity state. Therefore, it will be further appreciated that even if some amount of current does flow through the pro-fuse element of FIG. 6 after programming the amount of current will be less than for the pro-fuse elements pre-programmed conductive conductivity state, thereby allowing for a different logic state to be read after programming than before programming.

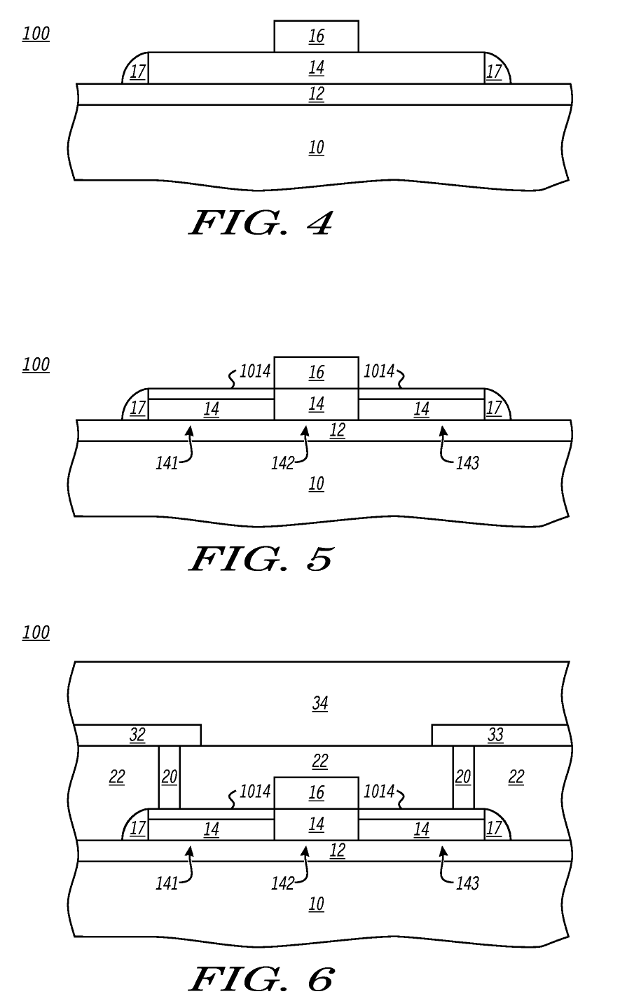

FIGS. 8 and 9 illustrate a specific embodiment of a workpiece 200 where a fuse element is being formed. The fuse element being formed at workpiece 200 is an anti-fuse element. Processing prior to FIG. 8 is similar to processing previously described, however the fuse element includes either a P-type or N-type polysilicon structure 214 formed overlying a dielectric 212. At FIG. 9, workpiece 200 includes a blocking structure 216 that has been formed overlying the polysilicon structure 214 in a similar manner as previously discussed with respect to blocking structure 16. In addition, a silicide 2214 is formed at portions 241 and 243 of structure 214 to form silicide portions. A portion 242 of polysilicon structure 214 remains unsilicided after the silicidation process. In addition, a doping process, represented by arrows 290, is illustrated at FIG. 9 that occurs after formation of blocking structure 216 so that portions 241 and 243 of polysilicon structure 214, which are not protected by silicide block 216, are doped with a dopant resulting in their conductivity type being the opposite from the conductivity type of portion 242 of polysilicon structure 214, which is protected from the doping process by the silicide block 216.

For example, portions 241 and 243 of the polysilicon structure 214 are doped to be N-type regions when the polysilicon structure 214 a P-type structure prior to doping process 290, and portions 241 and 243 of the polysilicon structure 214 are doped to be P-type regions when the polysilicon structure 214 an N-type structure prior to doping process 290. The resultant P-N-P or N-P-N structure of the polysilicon structure 214 results in formation of an anti-fuse element, which for a specific operating voltage, such as a read voltage applied during a read operation, prevents current from passing between portions 241 and 243, i.e., through portion 242, during a read operation. However, during programming, a programming voltage is applied that results in a programming current being provided from the silicided portion 241 to the silicided portion 243 through the non-silicided portion 242.

During a program operation of the anti-fuse element of workpiece 200, a program voltage at the anti-fuse exceeds the punch-through voltage of the N-P-N or P-N-P junction, i.e., the fuse link region, causing bipolar-type snap back to occur, thereby providing a programming current through the region 242 underling the silicide block, which is between regions 241 and 243. The nature of the bipolar snapback is such that the program current is localized and generates high temperature to form conducting filaments through the base region at portion 242. In addition, the high snapback current initiated by punch through of an N-P-N or P-N-P junction leads to thermal breakdown of the junction and forms permanent current path through the base region at portion 242. This thermal breakdown is enhanced by an elevated temperature at the fuse link that results during snapback by current passing through the unsilicided portion 242 of the polysilicon structure where resistance is higher than silicided portions 241 and 243. For example, it has been demonstrated that the anti-fuse of FIG. 9 can be programmed using a programming voltage of no more than 5 volts for a 0.13-micron semiconductor process, which can result in applying a current of 4 milliamps or less during programming.

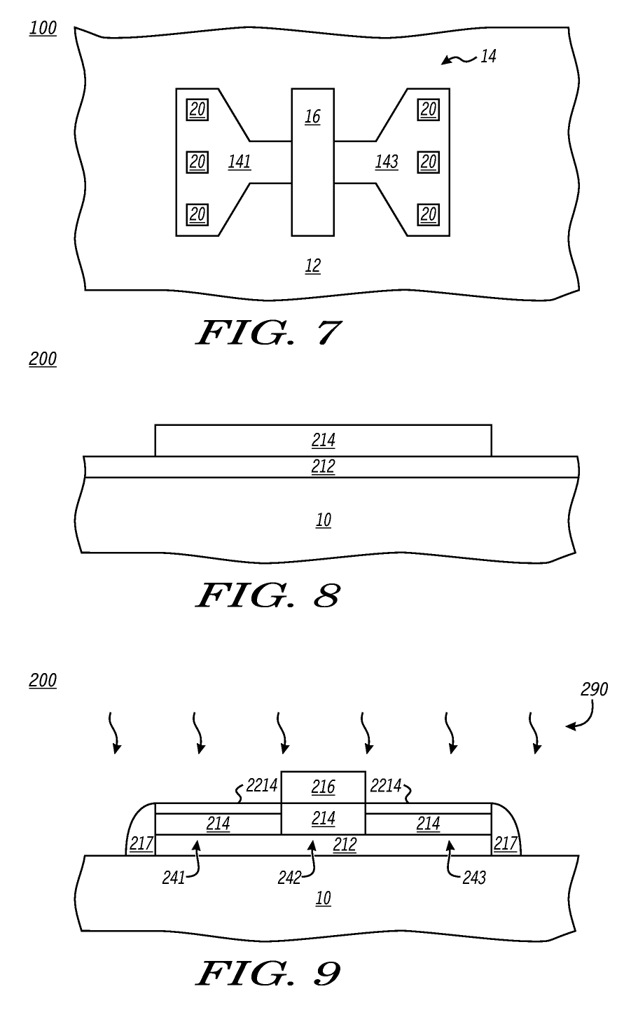

FIGS. 10 and 11 illustrate another embodiment of a fuse element in accordance with the present disclosure. The fuse element of workpiece 300 of FIG. 10 includes trench isolation region 351 that defines an active region 319. In one embodiment the well in active region 319 is a P-type region. N-type source/drain regions 311 and 313 are formed within region 319. The conductive gate electrode 314 is a discontinuously silicided polysilicon structure of the fuse element of FIG. 10 that can be formed in a similar manner as the discontinuously silicided polysilicon structure 14 of FIGS. 1-6. A dielectric layer 312, such as a gate dielectric, is formed under conductive gate electrode 314. Conductive inter-level interconnects 321 and 322 are formed between metal lines 331 and 322, respectively. An inter-level dielectric layer 320 overlies the substrate and active parts of anti-fuse element. Inter-level dielectric 330 overlies inter-level dielectric 320 and metal lines 331 and 332.

FIG. 11 illustrates a top view of portions of the fuse element of FIG. 10. In addition to those features described with reference to FIG. 10, FIG. 11 illustrates a plurality of inter-level interconnects 340 to conductive gate electrode 314, and a blocking region 318 overlying the gate electrode 314, which results in gate electrode 314 being discontinuously silicided as previously discussed. As a result, portions 341 and 343 of the gate electrode 314 are silicided, while portion 342 of the gate electrode formed by poly-silicon structure 314, which underlies the silicide block, is unsilicided.

Therefore, workpiece 300 combines a selectively silicided polysilicon heat element to an otherwise typical gate oxide anti-fuse element. The anti-fuse element of FIGS. 10 and 11 can be programmed by applying a voltage different between the conductive gate 314 and a source/drain region that is higher than a rupture voltage of gate dielectric 312, i.e., the fuse link, to destroy the gate dielectric 312. When ruptured, conductive paths through the gate dielectric occur, resulting in a current flowing during read operations. The rupture voltage, i.e., program voltage, of the gate dielectric 312 is based on the gate dielectric thickness. The rupture voltage increases as the gate oxide thickness increases. In this embodiment, the rupture voltage can be reduced by current passing through the non-silicided portion of the polysilicon gate which is proximate the fuse link region, i.e., the gate dielectric, during application of the programming voltage to elevate, the temperature at the gate dielectric 312, i.e. the fuse link. A rupture voltage at the gate structure 314 of no more than 5 volts has been demonstrated for a 0.13-micron semiconductor process, and a gate dielectric thickness of about 30 angstroms.

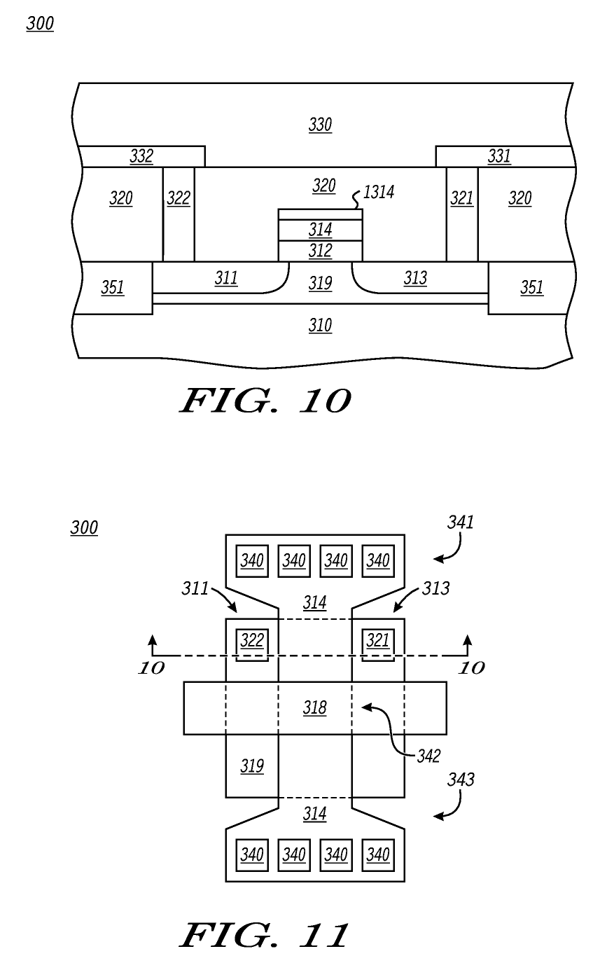

FIG. 12 illustrates a top view of an embodiment of a fuse element at a workpiece 400 that is formed using similar processes as those described with reference to FIGS. 1-6 to include a dielectric layer 412, a polysilicon structure 414 overlying dielectric layer 412, and a blocking structure 416 overlying polysilicon structure 414. The polysilicon structure 414 is formed as a discontinuously silicided polysilicon structure including silicide portions 441 and 443. However, the fuse element of workpiece 400 is formed having single conductive inter-level interconnects, e.g., vias or contact plugs, at least one of which acts as the fuse link of a pro-fuse at either end of the polysilicon structure 414. The inter-level interconnects 421 and 422 are electrically connected to metal lines 432 and 433, respectively. The pro-fuse element of workpiece 400 is programmed by applying a program current through the conductive inter-level interconnects 421 and 422 that destroys one or both of the conductive inter-level interconnects 421 and 422, resulting in a higher resistance path, such as an open circuit. Destruction of a conductive inter-level interconnect is facilitated by applying a current across the polysilicon structure 414 to generate heat proximate the region containing one or both of the conductive inter-level interconnects as a result of the programming current passing through the unsilicided portion 416 of polysilicon structure 414. Localizing this heat at one or both of the inter-level interconnects 421 and 422 facilitates blowing of an inter-level interconnect. In one embodiment, the silicide block is formed closer to one of contact plugs 421 and 422, to facilitate destruction of a specific contact plug. Note that while a single contact plug is illustrated at each end of the polysilicon structure more than one contact plug can be used, as well as different numbers of contact plugs at each end.

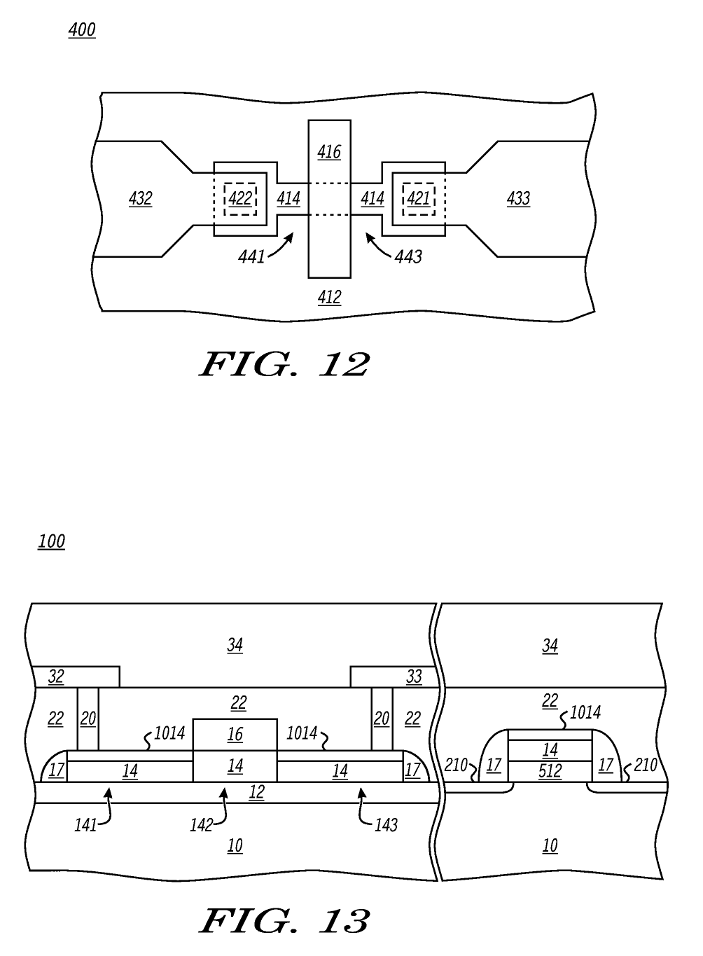

FIG. 13 illustrates the workpiece of FIG. 6 having a transistor formed from similar layers as the previously discussed fuse element. For example, layer 12 represents a shallow trench isolation region, and the gate structure of the illustrated transistor includes a gate dielectric 512, and a conductive gate structure formed from layer 14 overlying the gate dielectric. In addition, the transistor illustrated at FIG. 13 is illustrated to include lightly doped source/drain regions that can be doped at the same time that layer 14 is N-doped as previously discussed at FIG. 9. Note that the deep source/drain implants are not illustrated at FIG. 13.

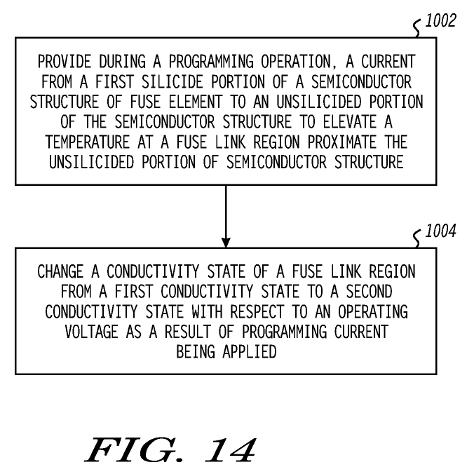

FIG. 14 illustrates a flow diagram in accordance with a specific embodiment of the present disclosure. At block 1002, a current is provided during a programming operation from a first silicide portion of a semiconductor structure, such as a polysilicon structure, an amorphous silicon structure, or other semiconductor structure of the fuse element to a second silicide portion of the semiconductor structure of the fuse element to elevate a temperature at a fuse link proximate the unsilicided portion of semiconductor structure. For example, with respect to the pro-fuse element illustrated at FIG. 6, and the anti-fuse element illustrated at FIG. 9, a programming current is provided from one silicided portion of a semiconductor structure of the fuse element to another silicided portion across an unsilicided portion of the fuse element that includes the fuse link. With respect to the anti-fuse element of FIGS. 10 and 11 the unsilicided portion 342 of the semiconductor structure 314, which underlies the silicide block 318, is provided a current from an adjacent silicided portion when a programming voltage is applied and the gate oxide 312 is ruptured during programming. As a result, an elevated temperature results at a portion of the gate oxide anti-fuse to further facilitate programming by assuring a conductive path between the gate electrode 314 and the underlying substrate. With respect to FIG. 12 the unsilicided portion 416 of the polysilicon structure 412 (a semiconductor structure) is proximate to at least one of the conductive inter-level interconnects 421 and 422 to elevate a temperature at a conductive inter-level interconnects during programming, in response to a current passing through polysilicon structure 414.

At block 1004 of FIG. 14, a conductivity state of the fuse link region is changed from a first conductivity state to a second conductivity state with respect to an operating voltage as a result of programming current being applied. As a result, a logic state read from the fuse element changes after programming. For example, with respect to the pro-fuse elements at FIG. 6, and FIG. 12, the first conductivity state represents a conductive state that allows current to flow at the operating voltage, and results in a 1^{st} logic state being read while the second conductivity state represents a non-conductive state that does not allow current to flow at the operating voltage and results in a 2^{nd} logic state being read. With respect to the anti-fuse elements at FIGS. 9 and 10, the first conductivity state represents a non-conductive state that prevents current from flowing at the operating voltage prior to programming, while the second conductivity state represents a conductive state that allows current to flow after programming at the operating voltage.

In the foregoing specification, principles of the invention have been described above in connection with specific embodiments. However, one of ordinary skill in the art appreciates that one or more modifications or one or more other changes can be made to any one or more of the embodiments without departing from the scope of the invention as set forth in the claims below. Accordingly, the specification and figures are to be regarded in an illustrative rather than a restrictive sense and any and all such modifications and other changes are intended to be included within the scope of invention. For example, it will be appreciated that providing a program current can be the result of a use applying a voltage to a node of the fuse element.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. Accordingly, the present disclosure is not intended to be limited to the specific form set forth herein, but on the contrary, it is intended to cover such alternatives, modifications, and equivalents, as can be reasonably included within the spirit and scope of the disclosure.

What is claimed is:

1. A method of forming an electronic device comprising:
forming a dielectric layer overlying a search substrate;
forming a semiconductor structure of a fuse element overlying the dielectric layer; and
siliciding a first portion of the semiconductor structure and a second portion of the semiconductor structure, wherein a third portion of the semiconductor structure that remains unsilicided is between and abutting the first portion and the second portion.

2. The method of claim 1 further comprising:
providing a current from the first portion to the second portion through the third portion to change a conductivity state of the fuse element from a first conductivity state to a second conductivity state during a programming operation, wherein the first conductivity is to be read as a first logic state during a read operation and the second conductivity state is to be read as a second logic state during the read operation.

3. The method of claim 2, wherein the first conductivity state is more conductive than the second conductivity state.

4. The method of claim 3, wherein providing the current further comprises providing less than 11 milliamps.

5. The method of claim 2, wherein the second conductivity state is less conductive than the first conductivity state.

6. The method of claim 5, wherein providing the current further comprises providing less than 4 milliamps.

7. The method of claim 1 further comprising:
forming a first conductive inter-level interconnect to a location of the first portion;
forming a second conductive inter-level interconnect to a location of the second portion, wherein a location of the third portion is equal-distant from the location of the first portion and the location of the second portion.

8. The method of claim 7, wherein a distance from the location of the first portion to the location of the second portion is less than approximately 2 micrometers.

9. A method comprising:
providing, during a programming operation, a current from a first silicide portion of a semiconductor structure of a fuse element to a second silicide portion of the semiconductor structure through a non-silicide portion of the semiconductor structure to elevate a temperature at a fuse link region proximate the non-silicide portion; and
changing a conductivity state of the fuse link region, in response to providing the current, from a first conductivity state to a second conductivity state, wherein the first conductivity state is to be read as a first logic state for a read operation and the second conductivity state is to be read as a second logic state for the read operation.

10. The method of claim 9 wherein the first conductivity state is more conductive than the second conductivity state.

11. The method of claim 9 wherein the first conductivity state is less conductive than the second conductivity state.

12. The method of claim 9, wherein providing the current further comprises providing the current to the semiconductor structure overlying and abutting a gate dielectric.

13. The method of claim 9, wherein providing the current to elevate the temperature at the fuse link region includes elevating the temperature of the fuse link region at the non-silicide portion.

14. The method of claim 13, wherein the first conductivity state is more conductive that the second conductivity state.

15. The method of claim 13 wherein the first conductivity state is less conductive than the second conductivity state.

16. The method of claim 9, wherein providing the current to elevate the temperature at the fuse link region includes elevating the temperature of the fuse link region at a conductive inter-level interconnect.

17. The method of claim 9, wherein providing the current to elevate the temperature at the fuse link region includes elevating the temperature of the fuse link region at a dielectric region.

18. A device comprising:
a substrate;
a dielectric layer;
a first length of a semiconductor structure of a fuse element, the first length being silicided, wherein the dielectric layer is between the substrate and the semiconductor structure;
a second length of the semiconductor structure that is silicided; and
a third length of the semiconductor structure between and abutting the first length and the second length that is unsilicided, the third length having a first conductivity state prior to programming and the device operable to have a second conductivity state after programming.

19. The device of claim 18, wherein the first length and the second length are N-doped and the third length is P-doped.

20. The device of claim 18, wherein the first length and the second length are P-doped and the third length is N-doped.
